(19) United States
(12) Patent Application Publication
(10) Pub. No.: US 2016/0099230 A1
(43) Pub. Date: Apr. 7, 2016

(54) MULTI-CHIP PACKAGE, TEST SYSTEM AND METHOD OF OPERATING THE SAME

(71) Applicant: SK hynix Inc., Gyeonggi-do (KR)

(72) Inventors: Yong-Gu KANG, Gyeonggi-do (KR); Ho-Sung CHO, Gyeonggi-do (KR)

(21) Appl. No.: 14/663,112

(22) Filed: Mar. 19, 2015

(30) Foreign Application Priority Data
Oct. 1, 2014 (KR) 10-2014-0132552

(51) Int. Cl. H01L 25/065; H01L 23/48; H01L 21/768; G01R 31/02; H01L 21/66

(52) U.S. Cl. CPC H01L 25/0657; G01R 31/02; H01L 22/20; H01L 21/76898; H01L 23/481; H01L 2225/06596; H01L 2225/06541

(57) ABSTRACT

A multi-chip package includes: a plurality of semiconductor chips that are coupled with each other through normal through silicon vias and repair through silicon vias; a state detection device suitable for detecting connection states of the normal through silicon vias and the repair through silicon vias; and a repair control device suitable for comparing the connection state of the normal through silicon vias with the connection state of the repair through silicon vias, and controlling whether to perform a repair operation.

### CROSS-REFERENCE TO RELATED APPLICATIONS

The present application claims priority of Korean Patent Application No. 10-2014-0132552, filed on Oct. 1, 2014, which is incorporated herein by reference in its entirety.

### BACKGROUND

1. Field

Exemplary embodiments of the present invention relate to semiconductor designing technology and, more particularly, to a multi-chip package including a plurality of semiconductor chips and a method of operating the same, and a test system and a method of operating the same.

2. Description of the Related Art

Semiconductor devices, including Double Data Rate Synchronous Dynamic Random Access Memory (DDR SDRAM) devices, are being developed in various ways to satisfy user demand. Among these developments are package technology and, recently, multi-chip packages have been introduced. In a multi-chip package, a plurality of semiconductor chips are implemented in a single chip. A plurality of memory chips having memory functions are used to increase memory capacity, or a plurality of semiconductor chips having different functions are used to improve performance. Multi-chip packages may be classified into single-layer multi-chip packages and multi-layer multi-chip packages. Single-layer multi-chip packages are formed by disposing a plurality of semiconductor chips on a plane, while multi-layer multi-chip packages are formed by stacking a plurality of semiconductor chips.

When multi-layer multi-chip packages are formed using a plurality of semiconductor chips, input/output terminals of the semiconductor chips are wire-bonded with each other. However, since wire-bonding is disadvantageous in terms of high-speed operation and noise, Through Silicon Vias (TSV) are used to couple semiconductor chips of the multi-layer multi-chip package with each other. However, TSVs are formed to penetrate through two or more semiconductor chips and, therefore, a failure may occur in the TSV connection. It is then necessary to develop technologies for detecting and repairing TSV connection failures.

### SUMMARY

Various embodiments are directed to a multi-chip package capable of detecting connection states of a plurality of Through Silicon Vias (TSVs) and, when a connection failure occurs in the TSVs, performing a repair operation on the connection failure, and a method of operating the same.

Various embodiments are directed to a test system capable of controlling timing when a command signal for a test operation is enabled by calculating the number of target TSVs to be repaired based on the connection states of TSVs from the multi-chip package, and a method of operating the same.

In accordance with an embodiment of the present invention, a multi-chip package may include: a plurality of semiconductor chips that are coupled with each other through normal through silicon vias and repair through silicon vias; a state detection device suitable for detecting connection states of the normal through silicon vias and the repair through silicon vias; and a repair control device suitable for comparing the connection states of the normal through silicon vias with the connection states of the repair through silicon vias, and controlling whether to perform a repair operation.

Test data may be applied to each of the normal through silicon vias and the repair through silicon vias during a test operation.

The state detection device may include: a first normal/failed detector suitable for receiving test data transmitted through the normal through silicon vias and generating a first detection signal; and a second normal/failed detector suitable for receiving test data transmitted through the repair through silicon vias and generating a second detection signal.

The repair control device may include: a normal/failed counter suitable for receiving an output signal of the state detection device and counting a number of normal through silicon vias that are failed and a number of repair through silicon vias that operate normally; an enable controller suitable for comparing the number of normal through silicon vias that are failed with the number of repair through silicon vias that operate normally, and generating an enable control signal; and a control signal generator enabled in response to the enable control signal, suitable for generating a repair control signal for controlling repair operations of the normal through silicon vias and the repair through silicon vias.

In accordance with another embodiment of the present invention, a method of operating a multi-chip package including a plurality of semiconductor chips that are coupled with each other through normal through silicon vias and repair through silicon vias, the method may include: detecting connection states of the normal through silicon vias and the repair through silicon vias; and comparing the connection states of the normal through silicon vias with the connection states of the repair through silicon vias, and controlling whether to perform a repair operation.

The method of operating a multi-chip package may further include: applying a test data to each of the normal through silicon vias and the repair through silicon vias.

The detecting of the connection states may include: receiving test data transmitted through the normal through silicon vias and generating a first detection signal; and receiving test data transmitted through the repair through silicon vias and generating a second detection signal.

The comparing of the connection states may include: receiving a detection signal corresponding to the connection states and counting a number of normal through silicon vias that are failed and a number of repair through silicon vias that operate normally; comparing the number of normal through silicon vias that are failed with the number of repair through silicon vias that operate normally, and generating an enable control signal; and generating a repair control signal for controlling repair operations of the normal through silicon vias and the repair through silicon vias in response to the enable control signal.

In accordance with yet another embodiment of the present invention, a method of operating a multi-chip package including a plurality of semiconductor chips that are coupled with each other through normal through silicon vias and repair through silicon vias, the method may include: applying a test data to each of the normal through silicon vias and the repair through silicon vias; determining a number of normal through silicon vias that are failed, a number of normal through silicon vias that operate normally, a number of repair through silicon vias that are failed, and a number of repair through silicon vias that operate normally based on the test data; deciding whether to perform a repair operation based on the number of normal through silicon vias that are failed, the number of normal through silicon vias that operate normally, the number of repair through silicon vias that are failed, and the number of repair through silicon vias that operate normally to produce a decision result; and performing the repair operation based on the decision result.

The deciding of whether to perform the repair operation, the number of normal through silicon vias that are failed may be compared with the number of repair through silicon vias that operate normally.

The method of operating a multi-chip package may further include: detecting a time taken for performing the repair operation based on the number of normal through silicon vias that are failed, the number of normal through silicon vias that operate normally, the number of repair through silicon vias that are failed, and the number of repair through silicon vias that operate normally.

In accordance with yet another embodiment of the present invention, a test system may include: a multi-chip package which includes: a plurality of semiconductor chips that are coupled with each other through normal through silicon vias and repair through silicon vias, a state detection device suitable for detecting connection states of the normal through silicon vias and the repair through silicon vias, and a repair control device suitable for comparing the connection states of the normal through silicon vias with the connection states of the repair through silicon vias, and controlling whether to perform a repair operation; and a test device suitable for receiving the connection states of the normal through silicon vias and the repair through silicon vias and controlling when a test operation is performed on the multi-chip package.

The test device may include: a normal/failed counter suitable for receiving the connection states of the normal through silicon vias and the connection states of the repair through silicon vias, and counting the number of normal through silicon vias that are failed and the number of repair through silicon vias that operate normally; a repair time calculator suitable for calculating a number of target through silicon vias to be repaired based on an output signal of the normal/failed counter; and a command generator suitable for generating a command signal for controlling an operation of the multi-chip package based on the number of target through silicon vias to be repaired.

The command signal may correspond to at least one operation of the multi-chip package, and timing of when the command signal is enabled may be controlled based on the number of target through silicon vias to be repaired.

In accordance with still another embodiment of the present invention, a method of operating a test system for a multi-chip package including a plurality of semiconductor chips that are coupled with each other through normal through silicon vias and repair through silicon vias, and a test device are provided, the method may include: beginning a first test operation; deciding whether to perform a repair operation by determining a number of normal through silicon vias that are failed, a number of normal through silicon vias that operate normally, a number of repair through silicon vias that are failed, and a number of repair through silicon vias that operate normally; calculating a time taken for performing a program operation based on the number of normal through silicon vias that are failed, the number of normal through silicon vias that operate normally, the number of repair through silicon vias that are failed, and the number of repair through silicon vias that operate normally, to produce an operation time calculation result; performing the program operation; and beginning a second test operation based on the operation time calculation result.

A method of operating a test system may further include: beginning a third test operation based on the operation time calculation result, wherein an operation section of the second test operation is different from an operation section of the first test operation, and the third test operation and the first test operation share the same operation section.

A method of operating a test system may further include: generating a command signal corresponding to the second test operation and the third test operation based on the time taken for performing the program operation.

The time taken for performing the program operation corresponds to the number of target through silicon vias to be repaired among the normal through silicon vias.

The deciding of whether to perform the repair operation, the number of normal through silicon vias that are failed may be compared with the number of repair through silicon vias that operate normally.

In the deciding of whether to perform the repair operation, the number of normal through silicon vias that are failed may be compared with the number of repair through silicon vias that operate normally.

### BRIEF DESCRIPTION OF THE DRAWINGS

FIG. 1 is a block diagram illustrating a multi-chip package in accordance with an embodiment of the present invention.

FIG. 2 is a block diagram illustrating a state detection device shown in FIG. 1.

FIG. 3 is a block diagram illustrating a repair control device shown in FIG. 1.

FIG. 4 shows a table describing a relationship between an enable control signal and output signals of a normal/failed counter shown in FIG. 3.

FIG. 5 is a timing diagram illustrating an operation of the multi-chip package shown in FIG. 1.

FIG. 6 is a block diagram illustrating a test system in accordance with an embodiment of the present invention.

FIG. 7 is a block diagram illustrating a test device shown in FIG. 6.

FIG. 8 shows an operation of the test device shown in FIG. 7.

FIG. 9 is a flowchart describing a test operation of FIG. 8.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

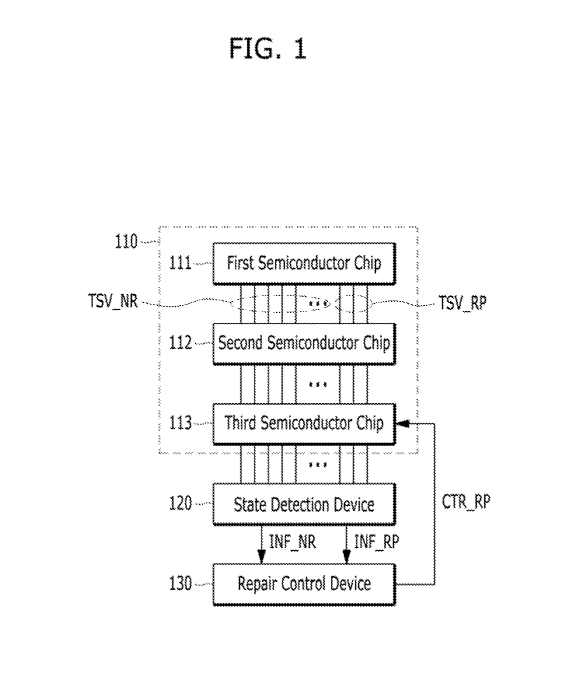

FIG. 1 is a block diagram illustrating a multi-chip package in accordance with an embodiment of the present invention.

Referring to FIG. 1, the multi-chip package includes a plurality of semiconductor chips 110, a state detection device 120, and a repair control device 130. Hereafter, to more simply explain the concepts of the present invention, an example of a multi-chip package having three semiconductor chips 111, 112 and 113 will be used. However, this is merely an example, and the present invention may be applied to multi-chip packages having two or more semiconductor chips.

The first to third semiconductor chips 111, 112 and 113 are coupled with each other through a plurality of Through Silicon Vias (TSVs) TSV_NR and TSV_RP, and share signals with each other and receive a required signal through the through silicon vias TSV_NR and TSV_RP. The through silicon vias TSV_NR and TSV_RP include a normal through silicon via TSV_NR and a repair through silicon via TSV_RP. The normal through silicon via TSV_NR is provided to perform a normal operation for an initially intended usage. The repair through silicon via TSV_RP is additionally provided to replace a through silicon via having a poor connection state among the normal through silicon vias TSV_NR. FIG. 1 shows three repair through silicon vias TSV_RP and more than three normal through silicon vias TSV_NR.

The state detection device 120 detects connection states of the normal through silicon vias TSV_NR and the repair through silicon vias TSV_RP, and generates a first detection information INF_NR corresponding to the connection state of the normal through silicon vias TSV_NR and a second detection information INF_RP corresponding to the connection state of the repair through silicon vias TSV_RP, The connection state of a through silicon via tells whether the through silicon via is properly connected, i.e., whether the through silicon via is in a normal connection state or a failed connection state. Therefore, the first detection information INF_NR has information on whether each of the normal through silicon vias TSV_NR is in a normal connection state or a failed connection state, which is referred to as normal/failed information, hereafter. The second detection information INF_RP has normal/failed information of each of the repair through silicon vias TSV_RP.

The repair control device 130 compares the first detection information INF_NR with the second detection information INF_RP outputted from the state detection device 120, and generates a repair control signal CTR_RP for controlling whether to perform a repair operation on the normal through silicon vias TSV_NR and the repair through silicon vias TSV_RP. The repair control device 130 receives the first detection information INF_NR and the second detection information INF_RP, counts the number of normal through silicon vias TSV_NR whose connection state is normal and the number of normal through silicon vias TSV_NR with a failed connection state, and counts the number of repair through silicon vias TSV_RP whose connection state is normal and the number of repair through silicon vias TSV_RP with a failed connection state. In other words, through the counting operation, the repair control signal CTR_RP is enabled when the number of failed normal through silicon vias TSV_NR is equal to or less than the number of normal repair through silicon vias TSV_RP, The third semiconductor chip 113 performs a repair operation in response to the enabled repair control signal CTR_RP.

Herein, the third semiconductor chip 113 that receives the repair control signal CTR_RP includes repair circuits for performing the repair operation. The repair circuits may include a circuit for storing an address of a target normal through silicon via to be repaired among the normal through silicon vias TSV_NR, and a circuit for controlling a repair through silicon via to be accessed, instead of the target normal through silicon via, when the target normal through silicon via is accessed.

The multi-chip package in accordance with the embodiment of the present invention may compare the connection state of the normal through silicon vias TSV_NR with the connection state of the repair through silicon vias TSV_RP and controls whether to perform a repair operation.

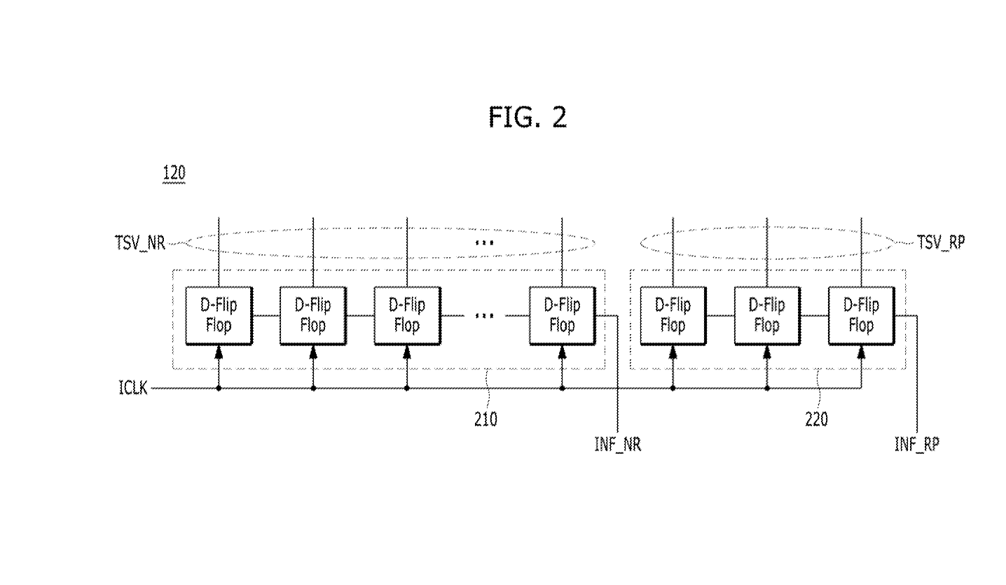

FIG. 2 is a block diagram illustrating the state detection device 120 shown in FIG. 1.

Referring to FIG. 2, the state detection device 120 includes a first normal/failed detector 210 for generating the first detection information INF_NR and a second normal/failed detector 220 for generating the second detection information INF_RP.

The first normal/failed detector 210 includes a plurality of D flip-flops that are respectively coupled with the normal through silicon vias TSV_NR, and the second normal/failed detector 220 includes a plurality of D flip-flops that are respectively coupled with the repair through silicon vias TSV_RP. Each of the D flip-flops performs a shifting operation in synchronization with an internal clock signal ICLK. The first detection information INF_NR and the second detection information INF_RP are generated through the shifting operation.

The normal through silicon vias TSV_NR and the repair through silicon vias TSV_RP are controlled to receive predetermined test data during a test operation. That is, each of the predetermined test data is controlled to pass through a corresponding one of the normal through silicon vias TSV_NR and the repair through silicon vias TSV_RP and be transmitted to a corresponding one of the first normal/failed detector 210 and the second normal/failed detector 220. Thus, if a failure occurs in the normal through silicon vias TSV_NR and the repair through silicon vias TSV_RP, the predetermined test data are not transmitted to the first normal/failed detector 210 and the second normal/failed detector 220. Therefore, the first detection information INF_NR and the second detection information INF_RP that are generated through the shifting operations of the first normal/failed detector 210 and the second normal/failed detector 220 have normal/failed information on the normal through silicon vias TSV_NR and the repair through silicon vias TSV_RP, respectively.

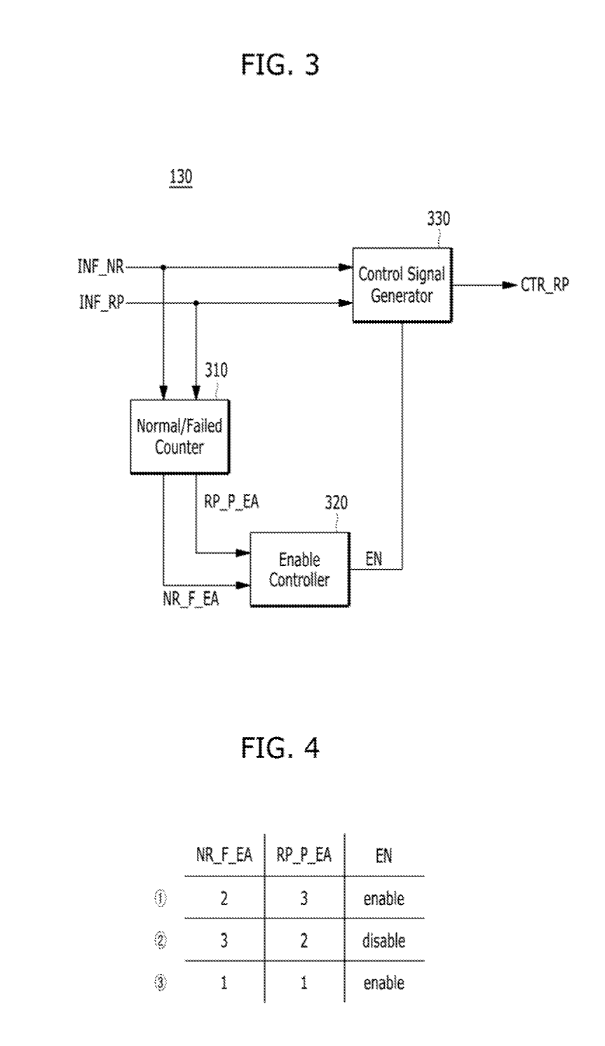

FIG. 3 is a block diagram illustrating the repair control device 130 shown in FIG. 1.

Referring to FIG. 3, the repair control device 130 includes a normal/failed counter 310, an enable controller 320, and a control signal generator 330.

The normal/failed counter 310 receives the first detection information INF_NR and counts the number of normal through silicon vias TSV_NR that operate normally and the number of normal through silicon vias TSV_NR that are failed, and receives the second detection information INF_RP and counts the number of repair through silicon vias TSV_RP that operate normally and the number of repair through silicon vias TSV_RP that are failed. The normal/failed counter 310 then provides the enable controller 320 with the counted values, particularly, the number NR_F_EA of the normal through silicon vias TSV_NR that are failed and the number RP_P_EA of the repair through silicon vias TSV_RP that operate normally.

The enable controller 320 compares the number NR_F_EA of the normal through silicon vias TSV_NR that are failed with the number RP_P_EA of the repair through silicon vias TSV_RP that operate normally, and generates an enable control signal EN. The conditions where the enable control signal EN is enabled may depend on design options, and for the sake of convenience in description, it is assumed herein that the enable control signal EN is enabled when the number NR_F_EA of normal through silicon vias TSV_NR that are failed is equal to or less than the number RP_P_EA of repair through silicon vias TSV_RP that operate normally.

The control signal generator 330 is enabled in response to the enable control signal EN, and generates the repair control signal CTR_RP for controlling repair operations on the normal through silicon vias TSV_NR and the repair through silicon vias TSV_RP based on the first detection information INF_NR and the second detection information INF_RP. The repair control signal CTR_RP is enabled in response to the enable control signal EN. For example, if the enable control signal EN is disabled, the repair control signal CTR_RP is not enabled.

The multi-chip package in accordance with the embodiment of the present invention may control whether to perform a repair operation based on the number NR_F_EA of normal through silicon vias TSV_NR that are failed and the number RP_P_EA of repair through silicon vias TSV_RP that operate normally.

FIG. 4 shows a table describing a relationship between the enable control signal EN and the output signals NR_F_RA and RP_P_EA of the normal/failed counter 310 shown in FIG. 3.

Referring to FIG. 4, the number NR_F_EA of normal through silicon vias TSV_NR that are failed is ‘2’ and the number RP_P_EA of repair through silicon vias TSV_RP that operate normally is ‘3’ in case \textcircled{1}. In case \textcircled{1}, since the number NR_F_EA is smaller than the number RP_P_EA, the enable control signal EN is enabled. In response to the enabling of the enable control signal EN, the repair control signal CTR_RP is enabled and a repair operation is performed.

In case \textcircled{2}, the number NR_F_EA of normal through silicon vias TSV_NR that are failed is ‘3’ and the number RP_P_EA of repair through silicon vias TSV_RP that operate normally is ‘2’. In case \textcircled{2}, since the number NR_F_EA is greater than the number RP_P_EA, the enable control signal EN is disabled. In response to the disabling of the enable control signal EN, the repair control signal CTR_RP is disabled and a repair operation is not performed.

In case \textcircled{3}, since the number NR_F_EA of normal through silicon vias TSV_NR that are failed is identical to the number RP_P_EA of repair through silicon vias TSV_RP that operate normally, the enable control signal EN is enabled. In this case, in response to the enabling of the enable control signal EN, the repair control signal CTR_RP is enabled and a repair operation is performed.

As shown in cases \textcircled{1}, \textcircled{2} and \textcircled{3}, the enable control signal EN is enabled when the number NR_F_EA of normal through silicon vias TSV_NR that are failed is equal to or less than the number RP_P_EA of repair through silicon vias TSV_RP that operate normally, and a repair operation is performed in response to the enabling of the enable control signal EN.

In this way, the multi-chip package in accordance with the embodiment of the present invention is able to decide whether to perform a repair operation based on the number NR_F_EA of normal through silicon vias TSV_NR that are failed and the number RP_P_EA of repair through silicon vias TSV_RP that operate normally.

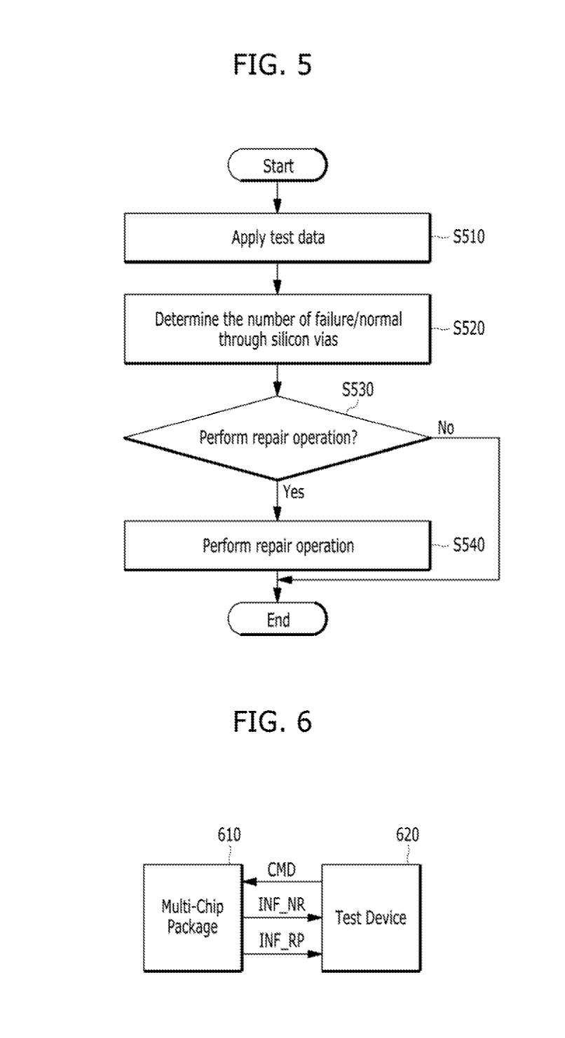

FIG. 5 is a timing diagram illustrating an operation of the multi-chip package shown in FIG. 1.

Referring to FIGS. 1 to 5, the operation of the multi-chip package includes a step S510 of applying the test data, a step S520 of determining the number of through silicon vias that operate normally and the number of through silicon vias that are failed, a step S530 of deciding whether to perform a repair operation, and a step S540 of performing a repair operation.

In step S510, the test data are applied to the respective through silicon vias, which include the normal through silicon vias TSV_NR and the repair through silicon vias TSV_RP.

In step S520, the number of through silicon vias that operate normally and the number of through silicon vias that are failed are determined. The number NR_F_EA of normal through silicon vias TSV_NR that are failed is determined by detecting the test data transmitted through the normal through silicon vias TSV_NR, and the number RP_P_EA of repair through silicon vias TSV_RP that operate normally is determined by detecting the test data transmitted through the repair through silicon vias TSV_RP.

In step S530, whether to perform a repair operation is decided based on the number NR_F_EA of normal through silicon vias TSV_NR that are failed and the number RP_PEA of repair through silicon vias TSV_RP that operate normally. When the number NR_F_EA is equal to or less than the number RP_P_EA, the enable control signal EN is enabled to perform the repair operation (YES). When the number NR_F_EA is greater than the number RP_P_EA, the enable control signal EN is disabled so that a repair operation (NO) is not performed.

In step S540, the repair operation is performed in response to the enabling of the enable control signal EN. That is, the repair operation is performed when the enable control signal EN is enabled, and the repair operation is not performed when the enable control signal EN is disabled.

In this way, the multi-chip package in accordance with the embodiment of the present invention may automatically decide whether to perform a repair operation based on the number NR_F_EA of normal through silicon vias TSV_NR that are failed and the number RP_P_EA of repair through silicon vias TSV_RP that operate normally, and perform the repair operation based on the decision result.

FIG. 6 is a block diagram illustrating a test system in accordance with an embodiment of the present invention.

Referring to FIG. 6, the test system includes a multi-chip package 610 and a test device 620.

The multi-chip package 610 includes a plurality of semiconductor chips that are coupled with each other through normal through silicon vias TSV_NR and repair through silicon vias TSV_RP. The multi-chip package 610 may have substantially the structure of the multi-chip package shown in FIG. 1. The multi-chip package 610 generates a first detection information INF_NR having normal/failed information on the normal through silicon vias TSV_NR and a second detection information INF_RP having normal/failed information on the repair through silicon vias TSV_RP.

The test device 620 receives the first detection information INF_NR and the second detection information INF_RP, which are information on the connection states of the normal through silicon vias TSV_NR and the repair through silicon vias TSV_RP, and generates a command signal CMD. The command signal CMD is a signal for controlling the multi-chip package 610, and it is assumed herein that the command signal CMD controls initial operations of diverse test operations.

The test system in accordance with the embodiment of the present invention may control timing when a test operation is performed based on the connection state of the normal through silicon vias TSV_NR and the repair through silicon vias TSV_RP.

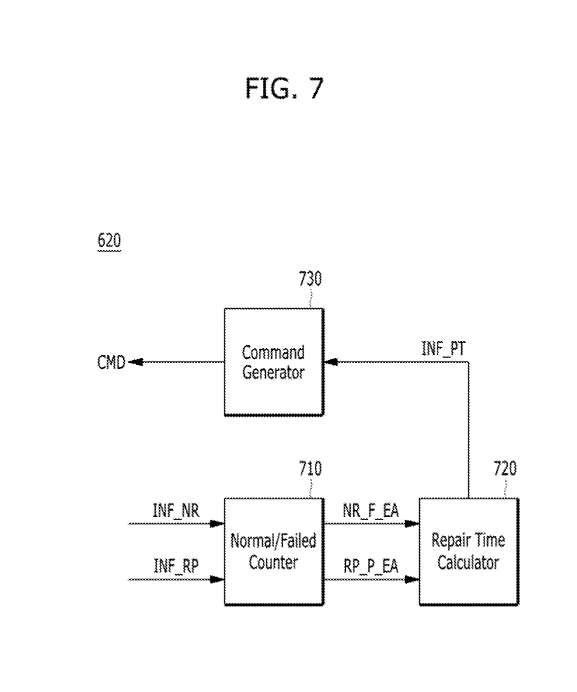

FIG. 7 is a block diagram illustrating the test device 620 shown in FIG. 6.

Referring to FIG. 7, the test device 620 includes a normal/failed counter 710, a repair time calculator 720, and a command generator 730.

The normal/failed counter 710 receives the first detection information INF_NR and counts the number of normal through silicon vias TSV_NR that operate normally and the number of normal through silicon vias TSV_NR that are failed, and receives the second detection information INF_RP and counts the number of repair through silicon vias TSV_RP that operate normally and the number of repair through silicon vias TSV_RP that are failed. The normal/failed counter 710 then provides the repair time calculator 720 with the counting value, particularly, the number NR_F_EA of normal through silicon vias TSV_NR that are failed and the number RP_P_EA of repair through silicon vias TSV_RP that operate normally.

The repair time calculator 720 calculates the number of target through silicon vias to be repaired (hereinafter, referring to repair target through silicon vias) based on the number NR_F_EA of normal through silicon vias TSV_NR that are failed and the number RP_P_EA of repair through silicon vias TSV_RP that operate normally. The repair time calculator 720 outputs repair operation time information INF_PT corresponding to the number of repair target through silicon vias.

Hereafter, for the sake of convenience in description, the repair operation time information INF_PT is briefly described.

Several circuits are required to perform a repair operation. Among them is a circuit for storing an address corresponding to a repair target through silicon via. Generally, a fuse circuit may be used as the circuit for storing the address corresponding to the repair target through silicon via. Hereafter, a series of operations for storing an address in a fuse circuit is simply referred to as ‘a program operation’. The program operation is an operation of rupturing a fuse based on the address corresponding to the repair target through silicon via, and it takes a predetermined time to perform a rupture operation. The repair operation time information INF_PT includes information on the time taken for performing the program operation. In other words, as the number of repair target through silicon vias increases, it takes more time to perform the program operation, and as the number of repair target through silicon vias decreases, it takes less time to perform the program operation.

The command generator 730 generates the command signal CMD in response to the repair operation time information INF_PT, The command signal CMD is a signal for controlling diverse test operations of the multi-chip package 610 shown in FIG. 6. In other words, the command generator 730 controls initial timings of the diverse test operations of the multi-chip package 610.

The test system in accordance with the embodiment of the present invention may calculate the number of repair target through silicon vias based on the connection states of the normal through silicon vias TSV_NR and the repair through silicon vias TSV_RP, and output the repair operation time information INF_PT corresponding to the number of repair target through silicon vias. Therefore, the test device 620 may control the timing when the command signal CMD corresponding to each of the diverse test operations is enabled, based on the repair operation time information INF_PT.

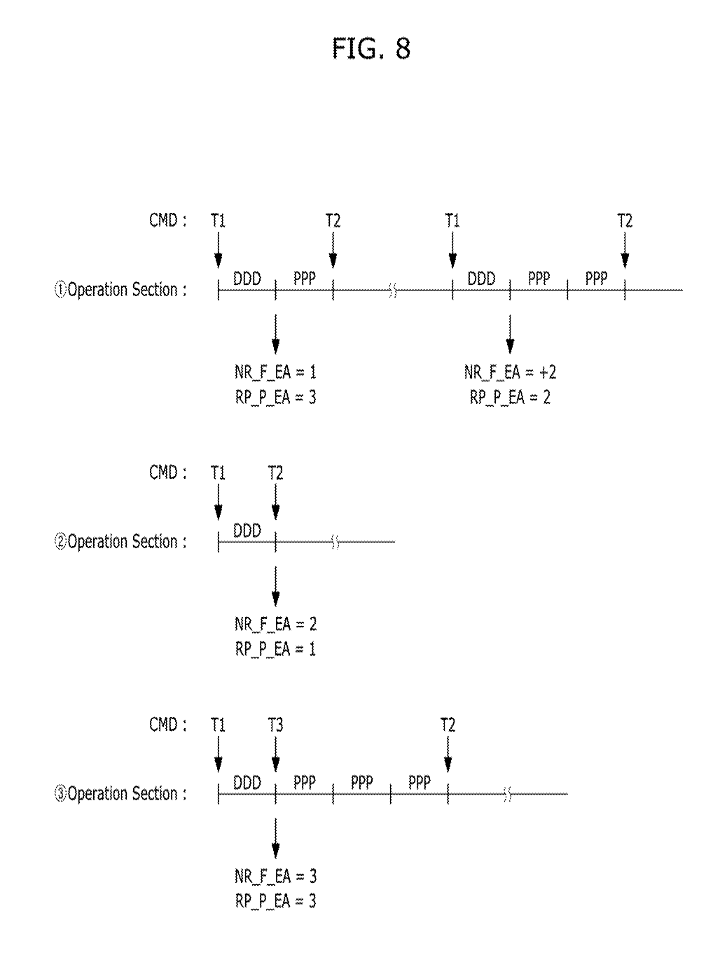

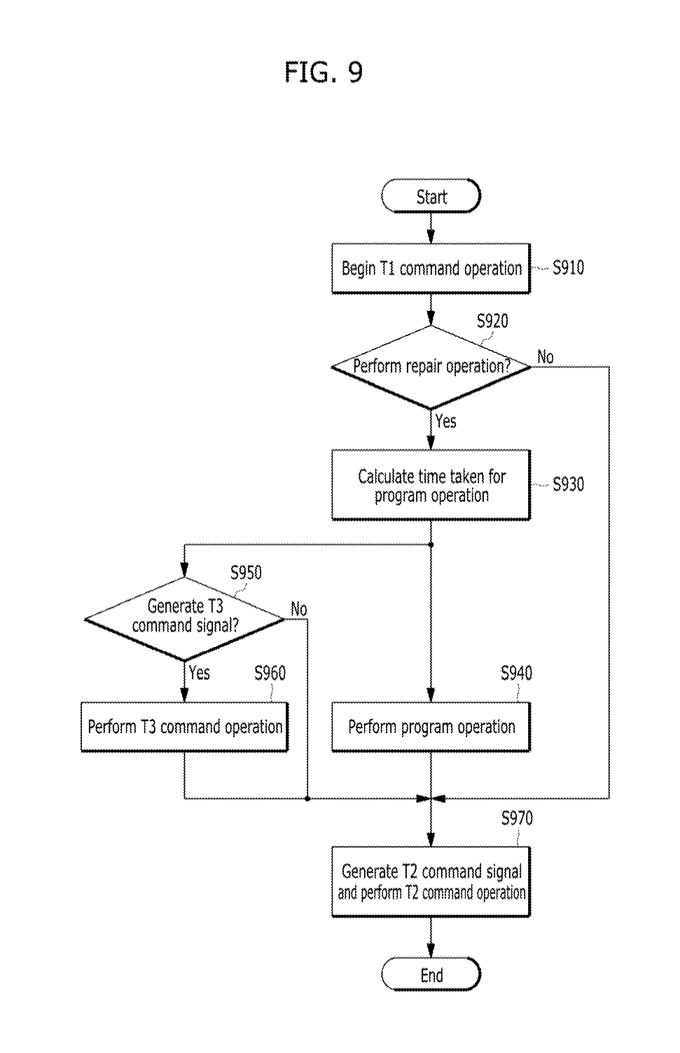

Hereinafter, the timing when the command signal CMD is enabled will be described in detail with reference to FIGS. 8 and 9.

FIG. 8 shows an operation of the test device 620 shown in FIG. 7. For the sake of convenience in description, three cases are taken as examples and described.

Referring to FIGS. 6 to 8, case \textcircled{1} shows a T1 command signal and a T2 command signal. The command signals control the operation of the multi-chip package 610. For example, the T1 command signal is a command signal for initiating an operation DDD for detecting connection states of the normal through silicon vias TSV_NR and the repair through silicon vias TSV_RP, and the T2 command signal is a command signal for the multi-chip package 610 initiating a predetermined operation after a program operation PPP.

The multi-chip package 610 performs the operation DDD for detecting the connection states of the normal through silicon vias TSV_NR and the repair through silicon vias TSV_RP in response to the T1 command signal, which is provided by the test device 620. For the sake of convenience in description, it is assumed that as a result of the operation DDD, the number NR_F_EA of normal through silicon vias TSV_NR that are failed is ‘1’ and the number RP_P_EA of repair through silicon vias TSV_RP that operate normally is ‘3’. The number NR_F_EA of normal through silicon vias TSV_NR that are failed being ‘1’ means that the number of repair target through silicon vias is ‘1’. As described earlier with reference to FIG. 4, since the number NR_F_EA is less than the number RP_P_EA, the multi-chip package 610 performs a program operation PPP for a repair operation. Since the number of repair target through silicon vias is ‘1’, the program operation PPP is performed once.

As mentioned above, the repair operation time information INF_PT corresponds to the time taken for performing the program operation. This signifies that the repair operation time information INF_PT corresponds to the program operation PPP, In other words, since the test device 620 has the repair operation time information INF_PT, it may be aware of when the program operation PPP ends in the multi-chip package 610, which is a target for the test operation, Therefore, when the multi-chip package 610 completes the program operation PPP, the test device 620 generates the T2 command signal immediately. Thus, the multi-chip package 610 may begin an operation corresponding to the T2 command signal directly after the program operation PPP.

Subsequently, the multi-chip package 610 may perform the operation DDD, which is an operation of detecting the connection states, in response to the T1 command signal that is provided by the test device 620. The operation DDD may be repeatedly performed because a normal through silicon via TSV_NR that is detected to operate normally during the operation DDD may come to have a connection failure later for some reason.

For the sake of convenience in description, it is assumed herein that as a result of the operation DDD in response to the second T2 command signal, the number NR_F_EA of normal through silicon vias TSV_NR that are failed is ‘3’, which is two more normal through silicon vias (+2) than the previous number of ‘1’, and the number RP_P_EA of repair through silicon vias TSV_RP that operate normally is ‘2’. Herein, the number RP_P_EA of the repair through silicon vias TSV_RP that operate normally means the number of repairable repair through silicon vias TSV_RP. In other words, since one repair through silicon via TSV_RP is used previously, two repair through silicon vias TSV_RP are usable, and this is described in the above in that the number RP_P_EA of repair through silicon vias TSV_RP that operate normally is ‘2’.

Subsequently, since the number NR_F_EA is equal to the number RP_P_EA, the multi-chip package 610 performs a program operation PPP. Since the number of repair target through silicon vias is ‘2’, the program operation PPP is performed twice. Subsequently, the test device 620 generates the T2 command signal, and the multi-chip package 610 begins an operation corresponding to the T2 command signal.

In case \textcircled{2}, the multi-chip package 610 performs the operation DDD for detecting connection states of normal through silicon vias TSV_NR and repair through silicon vias TSV_RP in response to the T1 command signal. For the sake of convenience in description, it is assumed that as a result of the operation DDD, the number NR_F_EA of normal through silicon vias TSV_NR that are failed is ‘2’ and the number RP_P_EA of repair through silicon vias TSV_RP that operate normally is ‘1’. As described earlier with reference to FIG. 4, since the number NR_F_EA is greater than the number RP_P_EA, the multi-chip package 610 does not perform a program operation PPP.

Meanwhile, since the test device 620 is aware that the multi-chip package 610 does not perform the program operation PPP based on the repair operation time information INF_PT, the test device 620 may generate the T2 command signal immediately. Through the immediate generation of the T2 command signal, the multi-chip package 610 may initiate an operation corresponding to the T2 command signal right after the operation DDD is performed.

Case \textcircled{3} shows the T3 command signal. The T3 command signal is a command signal CMD for controlling an operation of the multi-chip package 610, just like the T1 command signal and the T2 command signal. For example, the T3 command signal may be a command signal for initiating a preset operation regardless of the program operation PPP of the multi-chip package 610.

First of all, it is assumed herein that as a result of the operation DDD, the number NR_F_EA of normal through silicon vias TSV_NR that are failed is ‘3’ and the number RP_P_EA of repair through silicon vias TSV_RP that operate normally is ‘3’. In this case, the multi-chip package 610 performs the program operation PPP three times and may begin the predetermined operation corresponding to the T2 command signal after the program operation PPP three times.

Meanwhile, in case \textcircled{3}, while the multi-chip package 610 performs the program operation PPP three times, the test device 620 may generate the T3 command signal, which is not related to the program operation PPP. The multi-chip package 610 may begin the preset operation corresponding to the T3 command signal. Herein, the operation corresponding to the T3 command signal may include all operations that may be performed in a section where the program operation PPP is performed. As shown in FIG. 8, the operation corresponding to the T1 command signal and the operation corresponding to the T3 command signal may share the operation section with each other.

The test device 620 in accordance with the embodiment of the present invention may receive the first detection information INF_NR on the connection states of the normal through silicon vias TSV_NR and the second detection information INF_RP on the connection states of the repair through silicon vias TSV_RP from the multi-chip package 610, and generate the command signal CMD for the multi-chip package 610.

FIG. 9 is a flowchart describing a test operation of FIG. 8.

Referring to FIG. 9, the test device 620 includes step S910 of beginning a T1 command operation, step S920 of deciding whether to perform a repair operation, step S930 of calculating a time taken for performing a program operation, step S940 of performing the program operation, step S950 of deciding whether to generate a T3 command signal, step S960 of performing a T3 command operation, and step S970 of generating a T2 command signal and performing a T2 command operation, An operation corresponding to the T1 command signal is referred as the ‘T1 command operation’, an operation corresponding to the T2 command signal is referred as the ‘T2 command operation’, and an operation corresponding to the T3 command signal is referred as the ‘T3 command operation’.

In step S910, the T1 command operation begins. As described above with reference to FIG. 8, the operation for detecting the connection states of the normal through silicon vias TSV_NR and the repair through silicon vias TSV_RP is performed in step S910 in response to the T1 command signal.

In step S920, it is decided whether to perform a repair operation by counting the number NR_F_EA of normal through silicon vias TSV_NR that are failed and the number RP_P_EA of repair through silicon vias TSV_RP that operate normally. When the number NR_F_EA is equal to or less than the number RP_P_EA (YES), the logic flow goes to step S930 to perform the repair operation. Otherwise, when the number NR_F_EA is greater than the number RP_P_EA (NO), the logic flow goes to step S970 without performing the repair operation.

In step S930, the time taken for performing the program operation is calculated. As described above, the time taken for performing the program operation corresponds to the number of repair target through silicon vias among the normal through silicon vias TSV_NR.

In step S940, the program operation is performed. The information on the repair target through silicon vias is programmed.

Meanwhile, in step S950, it is decided whether to generate the T3 command signal. It is decided whether to perform an operation that is available to be performed, regardless of the program operation of step S940. Herein, whether to generate the T3 command signal is decided based on the time taken for performing the program operation, which is calculated in step S930. When a time taken for performing the T3 command operation in response to the T3 command signal is shorter than or equal to the time taken for performing the program operation (YES), the logic flow goes to step S960 to perform the T3 command operation. When the time taken for performing the T3 command operation in response to the T3 command signal is longer than the time taken for performing the program operation (NO), the logic flow goes to step S970 without performing the T3 command operation.

In step S960, following step S950, the T3 command operation is performed in response to the T3 command signal. Herein, as shown in case \textcircled{3} of FIG. 8, the program operation of step S940 and the T3 command operation of step S960 share the same operation section with each other.

Lastly, in step S970, the T2 command signal is generated and the T2 command operation is performed. In step S970, as described above with reference to FIG. 8, a command signal for a certain operation to be performed after the program operation PPP is generated and an operation corresponding to the generated command signal is performed.

The test device 620 in accordance with the embodiment of the present invention may control the initial timings for various command operations based on the connection states of the normal through silicon vias TSV_NR and the repair through silicon vias TSV_RP. Particularly, since the test device 620 may calculate the time taken for performing the program operation, the test device 620 may perform the T2 command operation immediately after the T1 command operation. Also, when the T1 command operation takes a long time to be performed, it may perform the T3 command operation while the T1 command operation is performed. This scheme saves the overall time taken for the test operation.

As described above, the multi-chip package in accordance with an embodiment of the present invention may control a repair operation based on the connection states of through silicon vias. Also, the operation of the multi-chip package may be efficiently controlled by transmitting the information on the connection states of the through silicon vias to a test device.

According to an embodiment of the present invention, a multi-chip package using a plurality of Through Silicon Vias (TSVs) may achieve highly reliable circuit operations.

While the present invention has been described with respect to the specific embodiments, it will be apparent to those skilled in the art that various changes and modifications may be made without departing from the spirit and scope of the invention as defined in the following claims.

What is claimed is:

1. A multi-chip package comprising:
a plurality of semiconductor chips that are coupled with each other through normal through silicon vias and repair through silicon vias;
a state detection device suitable for detecting connection states of the normal through silicon vias and the repair through silicon vias; and
a repair control device suitable for comparing the connection states of the normal through silicon vias with the connection states of the repair through silicon vias, and controlling whether to perform a repair operation.

2. The multi-chip package of claim 1, wherein test data is applied to each of the normal through silicon vias and the repair through silicon vias during a test operation.

3. The multi-chip package of claim 1, wherein the state detection device includes:
a first normal/failed detector suitable for receiving test data transmitted through the normal through silicon vias and generating a first detection signal; and
a second normal/failed detector suitable for receiving test data transmitted through the repair through silicon vias and generating a second detection signal.

4. The multi-chip package of claim 1, wherein the repair control device includes:
a normal/failed counter suitable for receiving an output signal of the state detection device and counting a number of normal through silicon vias that are failed and a number of repair through silicon vias that operate normally;
an enable controller suitable for comparing the number of normal through silicon vias that are failed with the number of repair through silicon vias that operate normally, and generating an enable control signal; and
a control signal generator enabled in response to the enable control signal, suitable for generating a repair control signal for controlling repair operations of the normal through silicon vias and the repair through silicon vias.

5. A method of operating a multi-chip package including a plurality of semiconductor chips that are coupled with each other through normal through silicon vias and repair through silicon vias, the method comprising:
applying a test data to each of the normal through silicon vias and the repair through silicon vias;
determining a number of normal through silicon vias that are failed, a number of normal through silicon vias that operate normally, a number of repair through silicon vias that are failed, and a number of repair through silicon vias that operate normally based on the test data;
deciding whether to perform a repair operation based on the number of normal through silicon vias that are failed, the number of normal through silicon vias that operate normally, the number of repair through silicon vias that are failed, and the number of repair through silicon vias that operate normally to produce a decision result; and
performing the repair operation based on the decision result.

6. The method of claim 5, wherein, in the deciding of whether to perform the repair operation,
the number of normal through silicon vias that are failed is compared with the number of repair through silicon vias that operate normally.

7. The method of claim 5, further comprising:
detecting a time taken for performing the repair operation based on the number of normal through silicon vias that are failed, the number of normal through silicon vias that operate normally, the number of repair through silicon vias that are failed, and the number of repair through silicon vias that operate normally.

8. A test system comprising:
a multi-chip package which includes:
a plurality of semiconductor chips that are coupled with each other through normal through silicon vias and repair through silicon vias,
a state detection device suitable for detecting connection states of the normal through silicon vias and the repair through silicon vias, and
a repair control device suitable for comparing the connection states of the normal through silicon vias with the connection states of the repair through silicon vias, and controlling whether to perform a repair operation; and
a test device suitable for receiving the connection states of the normal through silicon vias and the repair through silicon vias and controlling when a test operation is performed on the multi-chip package.

9. The test system of claim 8, wherein the test device includes:
a normal/failed counter suitable for receiving the connection states of the normal through silicon vias and the connection states of the repair through silicon vias, and counting the number of normal through silicon vias that are failed and the number of repair through silicon vias that operate normally;
a repair time calculator suitable for calculating a number of target through silicon vias to be repaired based on an output signal of the normal/failed counter; and
a command generator suitable for generating a command signal for controlling an operation of the multi-chip package based on the number of target through silicon vias to be repaired.

10. The test system of claim 9, wherein the command signal corresponds to at least one operation of the multi-chip package, and
timing of when the command signal is enabled is controlled based on the number of target through silicon vias to be repaired.
